(19) United States
(12) Patent Application Publication
(10) Pub. No.: US 2026/0193786 A1
(43) Pub. Date: Jul. 9, 2026

(54) METHOD FOR SETTING UP A CVD REACTOR

(71) Applicant: AIXTRON SE, Herzogenrath (DE)

(72) Inventors: Peter Sebald LAUFFER, Aachen (DE); Hassan LARHRIB, Herzogenrath (DE); Ilio MICCOLI, Herzogenrath (DE)

(21) Appl. No.: 19/132,766

(22) PCT Filed: Nov. 15, 2023
(86) PCT No.: PCT/EP2023/081907

§ 371 Date: May 23, 2025

(30) Foreign Application Priority Data
Nov. 23, 2022 (DE) 10 2022 130 987.8

(51) Int. Cl. C23C 16/52; C23C 16/455; C23C 16/458; G05B 19/4155; H10P 14/24

(52) U.S. Cl. CPC C23C 16/52; C23C 16/45512; C23C 16/4583; G05B 19/4155; G05B 2219/45031; H10P 14/24

(57) ABSTRACT

A method for predicting a change in values of a layer property or a local variable at a storage location at which a layer is deposited on a substrate. If an individual treatment parameter at a storage location is changed, not only do values that are attributable to the individual parameters at the storage location change, but so do the values at other storage locations. In the method, starting layers having individual starting parameters are deposited, and test layers having test parameters are deposited. From detected starting and test values, a sensitivity matrix can be formed with elements that each indicate the influence of a change in each of the individual parameters on each of the values of the layer property or local variable. By inverting the sensitivity matrix, correction parameters can be calculated in order to pre-set individual parameters, by means of which specified target values can be achieved.

### RELATED APPLICATIONS

This application is a National Stage under 35 USC 371 of and claims priority to International Application No. PCT/EP2023/081907, filed 15 Nov. 2023, which claims the priority benefit of DE Application No. 10 2022 130 987.8, filed 23 Nov. 2022.

### FIELD OF THE INVENTION

The invention relates to a method for predicting the change in target values of a layer property of layers or layer sequences deposited on several substrates arranged at different storage locations in a process chamber or of a local variable influencing the layer growth at the storage location. The invention further relates to a method for setting up an apparatus for simultaneously depositing one layer or layer sequence each on several substrates in a process chamber, wherein gases are fed into the process chamber according to predetermined treatment parameters and/or temperatures in the process chamber are set, wherein the treatment parameters contain individual parameters assigned individually to the various substrates, which may be individually changed.

The invention further relates to an apparatus with a control device for simultaneously depositing one layer or layer sequence each on several substrates, and to a method for simultaneously depositing one layer or layer sequence each on several substrates.

### BACKGROUND

US 2018/0340259 A1 describes a method for simultaneously depositing multiple layers on multiple substrates. Different gases may be fed from a gas inlet element at different azimuthal positions into a process chamber, the bottom of which is formed by a rotating susceptor on which several substrates are arranged around the axis of rotation. The substrates may be heated with zone heating devices, wherein the zones extend in the circumferential direction about the center of rotation. To optimize the layer homogeneity and in particular the layer thickness, a sensitivity matrix is formed with respect of the treatment parameters for feeding energy into the heating zones, with which the treatment parameters may be changed.

DE 10 2018 101 173 A1 describes a method for optimizing layer properties of a layer sequence that is deposited on a substrate. A coefficient matrix is formed and an inverted matrix is created therefrom.

WO 01/90434 A2 also describes the setting up of a sensitivity matrix in order to optimize the deposition of layers on substrates.

WO 02/092876 A1 describes an apparatus for depositing layers on substrates. In preliminary tests, the influences of changes in treatment parameters on the layer properties are determined. Correction values may be formed from an inverse function created therefrom.

US 2016/0336215 A1 describes a calibration method for correcting treatment parameters, in which a sensitivity matrix is formed and an inverse matrix created from this.

DE 10 2019 104 433 A1 and DE 10 2020 107 517 A1 describe such a CVD reactor. A susceptor that forms the bottom of a process chamber carries a multiplicity of substrates in a symmetrical arrangement about its center, which are coated by feeding of process gases through a gas inlet element arranged in the center of the process chamber. For this purpose, the susceptor is heated from below with a heating device. The heating device is a cooled RF coil. A temperature-control gas may be fed in between the RF coil and the underside of the susceptor, wherein the temperature-control gas is fed in in such a way that it individually influences the net heat transport from the heating device to the substrate. The heat flow to the individual substrates may thus be individually changed by means of an individual parameter.

DE 10 2018 124 957 A1 also describes such a CVD reactor. A susceptor forming the bottom of a process chamber carries a multiplicity of substrate holders in a symmetrical arrangement about its center, which rest on gas cushions and carry one or more substrates. The gas cushion is generated by a temperature-control gas that is fed into a pocket of the susceptor that holds the substrate holder. The height of the gas cushion or the thermal conductivity of the temperature-control gas individually influences the heat transport from the heating device to the substrate. For this purpose, the temperature-control gas flows may be individually set and changed using individual parameters.

DE 10 2014 104 218 A1 and 10 2020 123 326 A1 describe a CVD reactor in which a purge gas may be individually fed into a feeder zone in front of a substrate, the flow of which may be adjusted via individual parameters.

It has been observed that a change in one of these individual parameters causes a change not only to a value of a layer property of the layer or layers deposited with the changed individual parameter, but also a change to a value of the layer property of a layer or layer sequence deposited on a different substrate. Layer properties are understood to mean any properties of a layer or layer sequence deposited on a substrate. For example, a layer property may be a layer thickness predetermined by the growth rate of the layer, which may be measured on the deposited layer. Another layer property may be a layer composition. For example, a layer may be doped or consist of more than two components, so that the layer composition may be characterized by the amount of dopant incorporated into the layer or by the ratio of elements forming the layer. The layer may be a monocrystalline layer of a compound semiconductor that has more than two components, for example a GaAlN layer, in which the ratio of Al to Ga can depend on the individual parameters. Or a layer property may also be a property of a layer sequence, for example when vertical cavity surface emitting laser (VCSEL diodes) are manufactured. In this context, Bragg reflectors, each consisting of a multiplicity of layers are deposited, in which the layer thickness and the layer composition have a considerable influence on the wavelength of the VCSEL diodes. It has been observed that even the smallest temperature differences on substrates arranged adjacently in the process chamber or the smallest differences in the growth rates lead to intolerable deviations of the wavelengths from a target wavelength. A change in a cooling gas flow or a gas cushion flow carrying a substrate holder has influences on the growth of layers on neighbouring substrates because the individually changed gas flow can lead to pressure inhomogeneities in the process chamber, and/or because dilution effects take effect. These cross-dependencies are considered disadvantageous.

However, local variables at the storage location may also be influenced with the parameters assigned individually to the storage locations, wherein such local variables are understood to be technologically relevant environmental variables, such as a temperature, in particular a substrate temperature, a flow rate of a gas or a partial pressure of a process gas. If the local variable at one storage location is specifically changed using the individual parameter, this also leads to changes in the local variable at another storage location. The local variable influences the deposition of the layer in each case.

### SUMMARY OF THE INVENTION

The invention deals with the problem of specifying measures with which these cross-dependencies can be reduced. A method for setting up a CVD reactor is to be specified with which the deviations of values of the layer properties that are deposited on neighbouring substrates are minimized. The same applies to deviations of local variables. Further, a method is needed with which a prediction can be made as to how target values of a layer property or of a local variable will change at the storage location if one or more individual parameters are changed. The invention is based on the object of developing the method described in the prior art described in the introduction for predicting the changes in values using a sensitivity matrix, of specifying a method based on this for setting up an apparatus for the simultaneous deposition of layers or layer sequences at spatially different storage locations in a process chamber, and of characterizing an apparatus for this purpose.

The problem is solved by the invention specified in the claims, wherein the subclaims are not only advantageous developments of the invention specified in the independent claims, but also independent solutions to the problem.

According to the invention, the method described in the introduction is further developed in such a way that the treatment parameters are formed from a parameter individually assigned to each of the storage locations. These individual parameters have the same effect at each of the storage locations assigned to them, so for example a change in the treatment parameter affects the property of a layer there in the same way as at any other of the storage locations. And a change in the individual parameter also influences the values of the layer property at another of the storage locations.

The starting point of the invention is the realization that a change in an individual parameter is not only a change in a value of a layer property of the layer or layer sequence deposited with the changed individual parameter, but that this change also results in the value of the layer property of a layer or layer sequence deposited on a different substrate, and the realization that a change of a local variable due to a local change of an individual parameter also leads to the local variables at other storage locations. The individual parameter may be any treatment parameter with which a value of a layer property of a substrate can influence individually. The individual parameter may be the value of a purge gas flow, the value of a temperature-control gas flow, the mechanical position of a body influencing the temperature in the process chamber, the mass flow of a precursor, if this treatment parameter can be changed individually for at least some of the substrates or for some substrate holders each carrying at least one substrate. The layer composition and in particular an incorporation of dopant may be influenced by the mass flow of the precursor. The individual parameter may in particular be any mass flow or energy flow, such as a heating power. The value of the layer property may be the abovementioned layer thickness, which depends on the growth rate and the growth duration, a layer composition or a wavelength dependent on the layer thickness and the layer composition. The aim of the method is initially to enable a prediction to be made as to the extent to which a change in an individual parameter that is primarily only effective locally will influence the target value of a layer property or local variable at other storage locations. A further aim is to specify individual correction parameters, individual target parameters or individual correction factors with which individual parameters, which are provided by a recipe, for example, are corrected in such a way that the cross-dependencies mentioned above are largely reduced.

First and foremost, it is suggested that preliminary tests be carried out in which the cross-reactions are quantified. Thus, in a first preliminary test, a starting layer or a starting layer sequence may be deposited on a multiplicity of first substrates simultaneously, each using a first set of individual starting parameters. The individual starting parameters preferably have the same value for all substrates or substrate holders. Values of layer properties are determined on the layers or layer sequences deposited in this way. The values of the layer properties may be determined outside the process chamber. However, it may also be carried out during deposition by in-situ measurement, for example by observing a light wavelength using a spectrometer. In one variant, a local variable such as a surface temperature of the substrate or a surface temperature of a substrate holder may be measured at each storage location instead of the layer property but also during the deposition of the layer. In at least one second preliminary test, one test layer or test layer sequence each is deposited on a multiplicity of second substrates, also simultaneously with a second set of individual parameters, namely test parameters. The test parameters differ from the start parameters by at least one value. The values of the test parameters preferably have the same value except for one test parameter. The test parameters may differ from the start parameters in that only one test parameter assigned to a single substrate or substrate holder differs from the start parameter, and the other test parameters are identical to the start parameters. With a symmetrical arrangement of substrates or substrate holders in the process chamber, it may be sufficient to carry out only one second preliminary test, in which only a single test parameter differs from the start parameters. Otherwise, it may be necessary to carry out a second preliminary test for each individual parameter of the set of individual parameters, in which a different, but preferably only one test parameter differs from the starting parameter in each case. The layers or layer sequences deposited in the one or more second preliminary tests may then optionally be measured outside the process chamber, wherein the test values of the layer properties are determined. In the variant, the local variable, such as the surface temperature of the substrate or a surface temperature of the substrate holder may be measured at each storage layer instead of the layer property but also during the deposition of the layer. A sensitivity matrix is thereupon created from these test parameters and test values. An element of the sensitivity matrix may be a quotient of a difference value. If only one second preliminary test is carried out with a symmetrical arrangement of the substrates or substrate holders, only one second preliminary test needs to be carried out. This returns the elements of the sensitivity matrix of one column. The elements of the other columns are generated by cyclic substitution. A quotient may be formed to generate an element of the sensitivity matrix. The quotient consists of a difference value and the parameter difference by which the one test parameter differs from the start value.

The difference value may be formed in various ways. In a preferred variant of the invention, a test response is calculated, wherein to this purpose a first difference between the start value and an average of all start values and a second difference between the test value and an average of all test values are formed. The difference value is then the difference between the first difference and the second difference. However, the difference value may also be a difference between the start value and the test value or at least may contain one of the two averages. The sensitivity matrix compiled in this way forms the basis for making a prediction of the change in the target values that accompanies a variation in an individual parameter. For example, the sensitivity matrix may be used to predict not only the change in the target value at the storage location to which the individual parameter is locally assigned, for example a growth rate of a layer deposited there or a temperature there. The sensitivity matrix may also be used to predict the change in the value of the layer property or the local variable at any other storage location, i.e. the way in which the individual parameter assigned to another storage location influences the growth rate of the deposited layer or the temperature at the other storage location.

The method described above provides the basis for a method for setting up an apparatus for the simultaneous deposition of layers or layer sequences on substrates arranged at local storage locations in a process chamber. In a subsequent step, the sensitivity matrix is inverted. The correction parameters, the individual target parameters or the individual correction factors may then be formed with the inverted sensitivity matrix and the starting values of the layer properties. The individual parameters may be values of gas flows or heat flows that are directed to substrates arranged at different locations in the same process chamber. The individual parameters may also be positions of bodies with which gas flows or heat flows within the process chamber are influenced and which are provided in large numbers, wherein said bodies are assigned individually to different substrates or substrate holders and can be shifted individually. According to a preferred variant of the invention, a susceptor arranged in the process chamber has a multiplicity of storage locations for substrates or substrate holders arranged rotationally symmetrically around a center, to which individual parameters are assigned, wherein said parameters influence a purge gas flow, a heat flow or a process gas flow to the substrate holder or the storage location. The individual correction parameters may be formed by multiplying the inverted sensitivity matrix by a vector that contains correction values. The correction values may be a difference between the starting value and a target value of the layer properties. For example, a target value may be a certain layer thickness, a certain layer composition or a certain characteristic wavelength of a layer sequence, for example a Bragg reflector. Or the target value may also be a local variable, such as a temperature or flow rate that is measurable at the storage location or a partial pressure of a process gas. In the first preliminary test, the individual parameters, for example gas flows that generate gas cushions or temperature-control gas flows to individual substrate holders, may have the same value. With the method described above, correction values are then first determined by forming a difference with the start values and the target values after the first preliminary test is carried out. Correction parameters can be formed by subsequent calculation of a sensitivity matrix and inversion thereof. With these correction parameters, the start parameters can be corrected in such a way that the same layer properties are achieved in subsequent processes in which layers or layer sequences are deposited with the start parameters corrected in this way. In particular, the method may also be used to bring the local variables to a uniform value or to set them individually. An individual correction factor may be the quotient of a sum of the start parameter and the correction parameter on the one hand and the start value on the other. Other individual parameters specified by a recipe may then be operated on, in particular multiplied by, such a correction factor in order to adjust them in such a way that the tolerances of the layer properties are reduced. The method described above is used in particular for operating apparatuses described in DE 10 2019 104 433 A1 or DE 10 2018 124 957 A1. The individual parameter may thus be a gas flow or a composition of a gas flow with which a gas cushion is generated that supports a substrate holder which is heated from below by heating a susceptor with a heating device. Or the individual parameter may also be a gas flow or a composition of a gas flow with which a heat transport from a heating device to a susceptor supporting the substrate holder can be influenced.

In embodiments of the invention, it may be provided that the change in an individual parameter changes not only one value, but two values at the same time, for example a temperature-control gas flow may influence both a substrate temperature and the growth rate, or the growth rate and at the same time a layer composition. A similar situation applies for a gas flow forming a gas cushion for a rotary-driven substrate holder. The variable of said gas flow can determine the temperature, the growth rate or the layer composition. Several individual parameters such as the temperature, the growth rate or the layer composition, which influence different values, may also be in place at the same time. By applying the method described above several times in succession, correction parameters may be created for several individual parameters. However, it is also possible to start with a start parameter set and carry out preliminary tests with different test parameter sets, with qualitatively different individual parameters being changed in the different sets. Starting from an operating point of the system defined by the start values, a sensitivity matrix may thus be generated which indicates the change in the value or several values when the one or other individual parameter is changed.

The invention further relates to an apparatus for depositing a layer or layer sequence on several substrates in a process chamber. The apparatus may include valves and mass flow controllers, which in turn are part of a gas mixing device. A process chamber may be arranged in a reactor housing. Inside the process chamber, a susceptor may have several storage locations for a plurality of substrates. With a gas inlet element, process gases supplied by a gas mixing device may be fed into the process chamber according to a recipe stored in a control device. The control device is also set up to direct gas flows or heat flows independently of one another to different substrates or substrate holders carrying one or more substrates according to individual parameters specified by the recipe. The control device should have correction factors for correcting the individual parameters. These may be stored in a memory of the control device. The control device is also set up so that the individual parameters provided by the recipe may be corrected with the correction factors. The control device may include a microcomputer or a microprocessor that is programmable with a program. The correction factors may also be elements of a matrix, wherein said matrix generally only consists of diagonal elements. The individual parameters can be multiplied with this correction matrix.

The invention further relates to a method for depositing a layer or layer sequence on multiple substrates, in which the correction factors are determined in the manner described above and have been stored in the control device. When the method is performed, individual parameters are used that have previously been changed with the correction factors.

The system for depositing layers on substrates works with individual parameters qᵢ, the change of which leads to a change in a value λᵢ. When the method according to the invention is performed, the start parameters

$${q}_{i}^{S}$$

may be understood as a vector.

$${q}_{i}^{S} = ( \begin{matrix}{q}_{1}^{S} \\ ⋮ \\ {q}_{n}^{S}\end{matrix} ) \qquad ( 1 )$$

With these start parameters

$${q}_{i}^{S} ,$$

layer properties with the starting values

$${λ}_{i}^{S}$$

are determined in the first preliminary tests, and can also be understood as a vector

$${λ}_{i}^{S} = ( \begin{matrix}{λ}_{1}^{S} ( {q}_{1}^{S} ) \\ ⋮ \\ {λ}_{n}^{S} ( {q}_{n}^{S} )\end{matrix} ) \qquad ( 2 )$$

The start values

$${λ}_{i}^{S}$$

differ from the target values

$${λ}_{i}^{Z} .$$

The target values are specifications for example, of wavelengths for example, which a Bragg reflector should have as a property. Typically, all target values

$${λ}_{i}^{Z}$$

have the same value. But the target values may also be local variables at the storage locations where the substrates are stored in the process chamber. For example, it may be a temperature. But the term target value is also generally understood to mean the value of a layer property or of a local variable at the storage location which is set in the case of a certain set of start parameters (vector).

The following describes an example of a method by which correction values Δλᵢ can be determined.

The correction values Δλᵢ are calculated from these target values and start values using the following equation.

$${λ}_{i}^{Z} = {λ}_{i}^{S} + Δ {λ}_{i} \qquad ( 3 )$$

The aim of the method is to determine target parameters with which

$${q}_{i}^{Z}$$

with which layers or layer sequences can be deposited whose layer properties, for example wavelengths, reach the target value

$${λ}_{i}^{Z} .$$

An Intermediate aim of the method is to determine correction parameters Δqᵢ with which the target parameters

$${q}_{i}^{Z}$$

can be from the start parameters

$${q}_{i}^{S} ,$$

for example according to the following equation calculated

$${q}_{i}^{Z} = {q}_{i}^{S} + Δ {q}_{i} \qquad ( 4 )$$

However, the method according to the invention also includes an associated preliminary stage in which initially only predictions about the changes to the values Δᵢ can be made.

In the second preliminary tests, test parameters

$${q}_{i}^{T}$$

are used, and may also be understood as a vector.

$${q}_{i}^{T} = ( \begin{matrix}\begin{matrix}\begin{matrix}\begin{matrix}{q}_{0} \\ ⋮\end{matrix} \\ {q}_{0} - Δ q\end{matrix} \\ ⋮\end{matrix} \\ {q}_{0}\end{matrix} ) \qquad ( 5 )$$

In this case, all elements of the vector except one element of the vector are kept at the same value of a uniform parameter q₀. Only one element of the vector differs from all other elements of the vector by a parameter difference Δq from the uniform parameter q₀.

The uniform parameter preferably has the value of the start parameter

$${q}_{0} = {q}_{0}^{S} \qquad ( 6 )$$

By measuring the layers or layer sequences deposited during the second preliminary tests, test values

$${λ}_{i}^{T}$$

are then determined, which can also be considered as a vector. Similarly, the local variables can also be measured during the second preliminary tests.

$${λ}_{i}^{T} = ( \begin{matrix}\begin{matrix}\begin{matrix}\begin{matrix}{λ}_{1}^{T} ( {q}_{0}^{T} ) \\ ⋮\end{matrix} \\ {λ}_{j}^{T} ( {q}_{0}^{T} - Δ q )\end{matrix} \\ ⋮\end{matrix} \\ {λ}_{n}^{T} ( {q}_{0}^{T} )\end{matrix} ) \qquad ( 7 )$$

If the apparatus has a non-symmetrical arrangement of storage locations for substrates, it may be necessary to carry out second preliminary tests corresponding to the number of storage locations, in which a different element of each vector of the test parameters differs from the uniform parameter. With a symmetrical arrangement, however, only one column of a test value matrix needs to be determined. The other columns are then obtained by a conjunction of the test values in the manner described above, namely by cyclic substitution.

$${λ}_{i}^{T} ( {q}_{j}^{T} ) = [ \begin{matrix}{λ}_{1}^{T} ( {q}_{1}^{T} - Δ q ) & ⋯ & {λ}_{1}^{T} ( {q}_{1}^{T} ) \\ ⋮ & ⋱ & ⋮ \\ {λ}_{n}^{T} ( {q}_{n}^{T} ) & ⋯ & {λ}_{n}^{T} ( {q}_{n}^{T} - Δ q )\end{matrix} ] \qquad ( 8 )$$

A sensitivity matrix S_{i,j} can be created from this test value matrix in various ways, with each element of the sensitivity matrix S_{i,j} representing a change in the test value when an individual parameter changes.

In a first alternative, an average of the starting values λ̅^̅{̅S̅}̅ and an average of the test values λ̅^̅{̅T̅}̅ are used to create the sensitivity matrix S_{i,j}.

$$\overline{{λ}^{S}} = \frac{1}{n} \sum {λ}_{i}^{S} \qquad ( 9 )$$

$$\overline{{λ}^{T}} = \frac{1}{n} \sum {λ}_{i}^{T} \qquad ( 10 )$$

From these two mean values λ̅^̅{̅S̅}̅λ̅^̅{̅T̅}̅ a test response

$${λ}_{i}^{TA}$$

is formed as follows.

$${λ}_{i}^{TA} = ( {λ}_{i}^{S} - \overline{{λ}^{S}} ) - ( {λ}_{i}^{T} - \overline{{λ}^{T}} ) \qquad ( 11 )$$

Using these test responses, the sensitivity matrix S_{i,j} can be as follows:

$${S}_{i , j} = [ \begin{matrix}\frac{{λ}_{1}^{TA} ( {q}_{0} - Δ q )}{Δ q} & ⋯ & \frac{{λ}_{1}^{TA} ( {q}_{0} )}{Δ q} \\ ⋮ & ⋱ & ⋮ \\ \frac{{λ}_{n}^{TA} ( {q}_{0} )}{Δ q} & ⋯ & \frac{{λ}_{n}^{TA} ( {q}_{0} - Δ q )}{Δ q}\end{matrix} ] \qquad ( 12 )$$

Alternatively, the sensitivity matrix S_{i,j} may also be calculated as follows

$${S}_{i , j} = [ \begin{matrix}\frac{{λ}_{1}^{T} ( {q}_{1}^{T} - Δ q ) - {λ}_{1}^{S}}{Δ q} & ⋯ & \frac{{λ}_{1}^{T} ( {q}_{1}^{T} ) - {λ}_{1}^{S}}{Δ q} \\ ⋮ & ⋱ & ⋮ \\ \frac{{λ}_{n}^{T} ( {q}_{n}^{T} ) - {λ}_{n}^{S}}{Δ q} & ⋯ & \frac{{λ}_{n}^{T} ( {q}_{n}^{T} - Δ q ) - {λ}_{n}^{S}}{Δ q}\end{matrix} ] \qquad ( 13 )$$

or the sensitivity matrix S_{i,j} may also be calculated as follows

$${S}_{i , j} = [ \begin{matrix}\frac{{λ}_{1}^{T} ( {q}_{0} - Δ q ) - {λ}_{1}^{S}}{Δ q} & ⋯ & \frac{{λ}_{1}^{T} ( {q}_{0} ) - {λ}_{1}^{S}}{Δ q} \\ ⋮ & ⋱ & ⋮ \\ \frac{{λ}_{n}^{T} ( {q}_{0} ) - {λ}_{n}^{S}}{Δ q} & ⋯ & \frac{{λ}_{n}^{T} ( {q}_{0} - Δ q ) - {λ}_{n}^{S}}{Δ q}\end{matrix} ] \qquad ( 14 )$$

The test parameters

$${q}_{i}^{T}$$

preferably each correspond to the uniform parameter q₀.

With the aid of a sensitivity matrix S_{i,j} created in this way, a prediction can be made about a value λᵢ, as follows, for example

$${λ}_{i} ← {S}_{i , j} Δ {q}_{i} \qquad ( 15 )$$

The sensitivity matrix S_{i,j} links the correction values Δλᵢ and correction parameters Δqᵢ as follows

$$Δ {λ}_{i} = {S}_{i , j} Δ {q}_{i} \qquad ( 16 )$$

By inversion of the sensitivity matrix S_{i,j} into an inverted sensitivity matrix

$${S}_{i , j}^{- 1}$$

$${S}_{i , j}^{- 1} = INV ( {S}_{i , j} ) \qquad ( 17 )$$

The correction parameters Δqᵢ may then be calculated directly from the correction values Δλᵢ

$$Δ {q}_{j} = {S}_{i , j}^{- 1} Δ {λ}_{i} \qquad ( 18 )$$

From this, correction factors kᵢ may be calculated as follows

$${k}_{i} = \frac{{q}_{i}^{S} + Δ {q}_{i}}{{q}_{i}^{S}} \qquad ( 19 )$$

With the correction factors kᵢ, the target parameters

$${q}_{i}^{Z}$$

may then be calculated as follows, where

$${q}_{i}^{S}$$

is the start parameter specified by the recipe.

$${q}_{i}^{Z} = {q}_{i}^{S} {k}_{i} \qquad ( 20 )$$

Individual parameters specified according to a recipe may be multiplied with these correction factors kᵢ in later production processes in order to correct them.

The invention also relates to a method with which a prediction of the change to two different target values

$${λ}_{i}^{Z} , {λ}_{i}^{′ Z}$$

is to be made, wherein two or more target values may each be a layer property of substrates arranged on several different storage locations in a process chamber, or a local physical variable influencing the layer growth in each case, such as an environmental property at the storage location. It is also provided that a first target value

$${λ}_{i}^{Z}$$

may be a layer property, for example a layer thickness or a wavelength of a Bragg mirror. The second target value

$${λ}_{i}^{′ Z}$$

may be a local variable at the storage location, for example a temperature, for example a substrate temperature. To carry out such a variant of the method, the previously described method may be performed several times in succession. In a first variant, it may be provided that in a first preliminary test with a set of starting parameters

$${q}_{i}^{S}$$

starting values

$${λ}_{i}^{S} , {λ}_{i}^{′ S}$$

of both the first value of the layer property or local variable and of the second value of the layer property of the local variable are determined. In subsequent preliminary tests, the individual parameters qᵢ are then varied in the manner described above, so that a first sensitivity matrix S_{i,j} is obtained, with which a prediction of the change in first values λᵢ can be made when a first individual parameter qᵢ changes, and a second sensitivity matrix

$${S}_{i , j}^{′}$$

is obtained, with which a prediction of the change in second values

$${λ}_{i}^{′}$$

can be made when a second individual parameter q changes. With a variant of such kind, it is thus possible to determine for example the change in a layer thickness or growth rate of the layer up to the thickness of a gas cushion, and the change in a surface temperature of the substrate up to a temperature-control gas flow.

It is also provided that two (or more) different parameters qᵢ and qᵢ influence two or more different target values

$${λ}_{i}^{Z} , {λ}_{i}^{′ Z}$$

simultaneously, but to different degrees. These parameters may be, for example, a gas used to rotate a substrate holder (rotation gas flow) and a temperature-control gas, wherein the two parameters may have different degrees of influence on both the layer thickness and the temperature. It is a further objective of this method optionally to consider the influence of several parameters on only one target value, on the layer thickness for example. For this purpose, one matrix S_{i,j} is determined correspondingly for the gas generating the rotation and one matrix

$${S}_{i , j}^{′}$$

for the temperature-control gas. Then, for example the parameters of the temperature-control gas are determined/adjusted with a method (not the subject matter of this method) in such a way that a desired substrate temperature profile is achieved under the given initial temperature deviation. The effect of the parameter change of the temperature-control gas on the target layer thickness is then predicted using the matrix

$${S}_{i , j}^{′} .$$

This initially unintended and unwanted secondary effect of the temperature-control gas on the target layer thickness may then be taken into account when determining the correction values for the gas generating the rotation with the aid of the matrix

$${S}_{i , j}^{- 1}$$

in equation 18 by adding to the correction values Δλᵢ and minimized with the correction parameters of the rotation gas flows.

It is therefore also provided that in order to predict the change in the values of the layer property or the local variable in further one or more third preliminary tests on a multiplicity of third substrates, a second test layer or second test layer sequence is deposited in each case simultaneously with a third set of second test parameters assigned to another individual parameter, which are different from the first test parameters. In the second preliminary tests, for example, the mass flow of the gas that generates the gas cushion on which the substrate holder lies or that causes the substrate holder to rotate may be changed. In this context the value may be the layer thickness and/or the temperature. When depositing the second test layers, the mass flow of the temperature-control gas may be changed. Here too, the layer thickness and/or the temperature may be determined as the value. Second test values of the same layer property, that is to say for example of the layer thickness or also of the layer composition, are then measured on the second test layers or test layer sequences, or second local variables, such as the temperature of the substrate, are measured. The second sensitivity matrices

$${S}_{i , j}^{′}$$

are then formed from the second test values of the layer property or the local variable. In this way, predictions can be made as to the extent to which two different parameters, for example the mass flow of the gas generating the gas cushion or the mass flow of the temperature-control gas, may influence the same layer property or the same local variable to different degrees.

However, it is also possible to carry out the method described above several times in succession and to determine starting values in each first preliminary test after each process step has been completed.

### BRIEF DESCRIPTION OF THE DRAWINGS

An embodiment of the invention is explained below with reference to the attached drawings. In the drawings:

FIG. 1 is a plan view of a susceptor 3 of a CVD reactor,

FIG. 2 is a section along line II-II in FIG. 1.

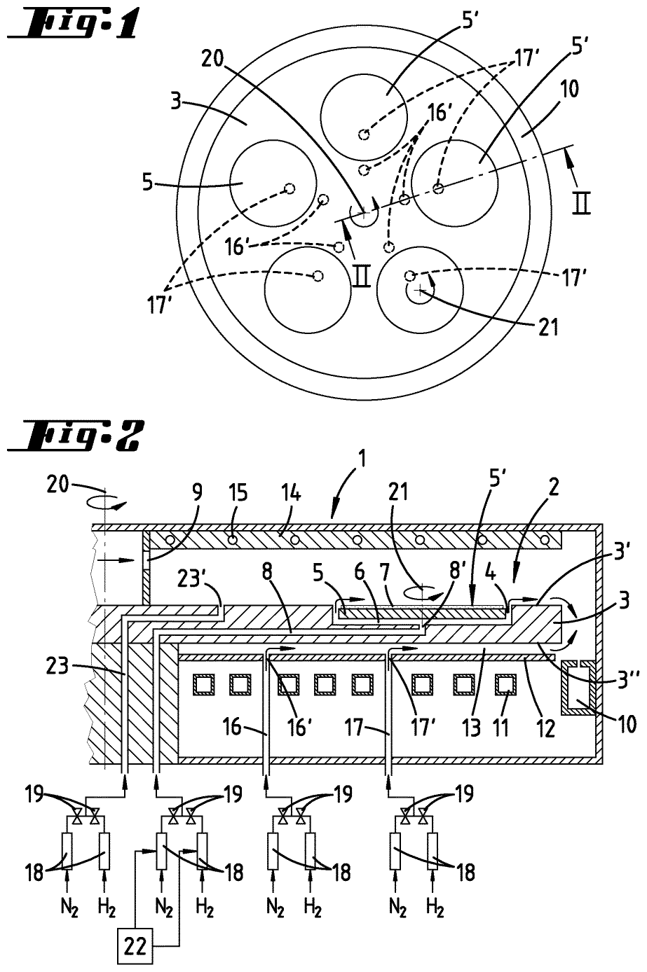

### DETAILED DESCRIPTION

An exemplary embodiment of an apparatus for carrying out a method for coating semiconductor substrates in particular with semiconductor layers has a reactor housing 1 which can be evacuated, and in which a process chamber 2 is located, and which may be made of stainless steel.

Below an upper wall of the housing 1, there is a process chamber ceiling 14, which may be cooled in the embodiment, for which purpose cooling channels form a cooling device 15. In the middle of the process chamber 2, there is a gas inlet element 9 with a gas outlet orifice for the exit of process gases. The process gases may be hydrides of elements of main group V and organometallic compounds of elements of main group III. These are fed into the process chamber 2 from the central gas inlet element 9 together with a carrier gas, which may be hydrogen, for example. The process gas and the carrier gas flow through the process chamber 2 in a radial direction from the inside to the outside. A gas outlet element 10 extends around the outer edge of the susceptor 3. Exhaust gases may be pumped out of the process chamber 2 through this gas outlet element 10 by means of a vacuum pump (not shown).

The floor of the process chamber 2 opposite the process chamber ceiling 14 is formed by a top side 3′ of the susceptor 3.

On the top side 3′ of the susceptor 3, there are several storage locations 5′, each for one substrate, the storage locations 5′ being arranged symmetrically about a center of the susceptor 3. It may also be possible for several substrates to be arranged on each of the storage locations 5′.

In the embodiment shown in the figures, there are a plurality of pockets 4 which have a base into which a feed line 8 opens. There is a substrate holder 5 in each pocket 4, which carries a substrate 7. By feeding a gas into the feed line 8, a gas cushion 6 is built up between the underside of the substrate holder 5 and the base of the pocket 4, which keeps the substrate holder 5 suspended and also drives it to rotate about an axis. In other embodiments of the invention, the substrate 7 may also rest directly on the susceptor 3, so that the susceptor 3 only has a plurality of storage locations for substrates 7.

A sealing plate 12 extends beneath the underside 3″ of the susceptor 3. A gap 13 is formed between the underside 3″ and the sealing plate 12. Feed lines 16, 17 open into the gap 13 at different radial positions from each other. An orifice 16′ is located radially inside the circular arc line extending around an axis of rotation 20 of the susceptor 3 and passing through the radially inner edges of the pockets 4. A second orifice 17′ of the feed line 17 is located underneath a pocket 4. In other exemplary embodiments of the invention, these orifices 16′, 17′ do not need to be present, or only one of these orifices 16′, 17′ needs to be present.

Below the sealing plate 12, there is a spiral-shaped coil that forms a heating device 11. The coil may be used to generate an RF field that generates eddy currents in the susceptor 3, causing the susceptor 3 to heat up. The coil of the heating device 11 is hollow. A coolant may flow through the cavity in the heating device 11. In other embodiments of the invention, the heating device may also be a resistance heater with which the susceptor 3 is heated, or a radiant heater with which the susceptor 3 is heated by thermal radiation.

The feed lines 8, 16, 17 are connected to a gas mixing system which has mass flow controllers 18 and valves 19, wherein the valves 19 and the mass flow controllers 18 are controlled by a control device 22. The control device 22 may have a microcontroller or microprocessor in which a memory is arranged that contains a program with which the mass flow controllers 18 and the valves 19 are controlled according to a program that is also stored in the memory.

A gas flow may be fed individually through individual feed lines 8 into each of the total of five pockets in the exemplary embodiment, each of which supports a substrate holder 5 on a gas cushion 6. The control device 22 may thus serve to individually adjust the gas cushions 6 of all substrate holders 5. The mass flow of the gas forming the gas cushion 6 may serve to individually adjust the height of the gas cushion 6 and therewith the distance of the substrate holder 5 from the base of the pocket 4. The mass flow of this gas not only influences the temperature of the surface of the substrate 7 carried by the substrate holder 5. A change in the mass flow also leads to a dilution of the process gas above the substrate 7, since the process gas fed into the pocket 4 flows into the process chamber 2 through the edge gap between substrate holder 5 and wall of the pocket 4. This influences the growth rate of the layer deposited on the substrate 7. This results in layers of different thicknesses being deposited on the substrates.

The layer composition of a ternary or quaternary semiconductor layer deposited on the substrate may be modified by changing the temperature of the substrate 7.

In the embodiment, at least one gas feed line 16, 17 through which a gas may be fed into the gap 13 opens under each of the substrate holders 5. If the susceptor 3 is rotated about its axis 20 during operation, the gas may be fed through the orifices 16′, 17′ in synchronization with the rotation of the susceptor 3. The gas flow through the gap 13 may be individually changed so that the heat conduction between the heated susceptor 3 and the cold coil 11 changes. The resulting change in heat flow causes the temperature of the substrate 7 to change.

The valves 19 and the mass flow controllers 18 may serve to feed a mixture of gases with different thermal conductivity properties into the feed lines 8, 16, 17, for example an adjustable mixture of nitrogen and hydrogen. By selecting the mixing ratio, the heat transport by thermal conduction may be adjusted either towards the substrate holder 5 or away from the susceptor 3, each individually below one of the substrates 7.

An additional temperature-control gas, which may also be a mixture of two gases with different thermal conductivity properties, may be fed in through an optional feed line 23, which opens radially inside the substrate 7 in the top side 3′ of the susceptor 3 with an orifice 23′. Here too, it is provided that each of the substrates 7 is individually assigned an orifice 23′, from which an individual gas mixture or an individual gas flow may be fed into the process chamber 2.

In a variant of the apparatus and/or method, a reactive gas may also be fed into the orifice 23′.

The invention relates both to apparatuses that have four of the previously described feed lines 8, 16, 17, 23 and to apparatuses that have only one or fewer than four of the previously described feed lines 8, 16, 17, 23. In principle, it is still sufficient to perform the method even if only one set of said feed lines is provided.

Precise control of the growth rate and precise control of the material composition for each of the substrates 7 is extremely important for the manufacture of VCSEL diodes. These variables have a direct influence on the wavelength of the light emitted by the diodes. The layer sequences deposited on the substrates 7 form Bragg mirrors. Here, the material composition, which is determined by the temperature, is a critical variable. Furthermore, the individual layer thickness there, which is determined by the growth rate, is also a critical variable. Even the smallest deviation between the individual wafers leads to defective results in production. However, the method is not only merely limited to the production of layer sequences to form a Bragg mirror, it also affects the production of layers or layer sequences for other components.

It has been found that changing one of the gas flows flowing through the feed lines 8, 16, 17, 23 not only influences the material composition and/or growth rate of the layer or layer sequence deposited on the respective associated substrate 7, but also the material composition and/or growth rate on other substrates 7 due to cross effects.

These gas flows and/or mixture ratios of the gases are referred to as individual parameters within this disclosure. The material composition and/or growth rate is referred to as a value within this disclosure.

One of the objects of the invention is to find target parameters

$${q}_{i}^{Z}$$

for individual parameters specified by a recipe, such as gas flows or mixture ratios of the gases, in order to achieve target values

$${λ}_{i}^{Z}$$

for the material composition, the layer thickness or, in the case of VCSEL diodes, the wavelength.

A method for setting up a CVD reactor with which layer sequences are deposited on the substrates 7, which form a Bragg mirror having the most uniform wavelength possible, in a first preliminary test uncorrected flows of a temperature-control gas are fed in through at least one of the previously described feed lines 8, 17, 16, 23. For example, the following gas flows are set with a uniform parameter q₀.

For example, the following gas flows are set with a uniform parameter λᵢ:

$${q}_{i}^{S} = ( \begin{matrix}400 sccm \\ 400 sccm \\ 400 sccm \\ 400 sccm \\ 400 sccm\end{matrix} ) \qquad ( 21 )$$

The five substrates in the exemplary embodiment are then measured, and the wavelength of the Bragg reflectors is determined. The following wavelengths of starting values

$${λ}_{i}^{S}$$

are determined

$${λ}_{i}^{S} = ( \begin{matrix}618.2 nm \\ 615.3 nm \\ 616.3 nm \\ 616.6 nm \\ 617.7 nm\end{matrix} ) \qquad ( 22 )$$

In a second preliminary test, another five substrates are coated with a layer sequence, although the gas flows are now not identical with each other. At least one gas flow is reduced by a parameter difference λq. For example, the following test parameter set is used.

$${q}_{i}^{T} = ( \begin{matrix}150 sccm \\ 400 sccm \\ 400 sccm \\ 400 sccm \\ 400 sccm\end{matrix} ) \qquad ( 23 )$$

These substrates are also measured with regard to the wavelength of the Bragg reflection, wherein the following test values

$${λ}_{i}^{T}$$

are measured:

$${λ}_{i}^{T} = ( \begin{matrix}623.9 nm \\ 613.5 nm \\ 612.3 nm \\ 612. nm \\ 610.9 nm\end{matrix} ) \qquad ( 24 )$$

Averages of the starting values λ̅^̅{̅S̅}̅ and averages of the test values λ̅^̅{̅T̅}̅ are then determined using equations 9 and 10. With the aid of these averages and the measured wavelengths, test responses

$${λ}_{i}^{TA}$$

are then determined according to equation 11.

When depositing the layer sequence in the second preliminary test, a gas flow of 400 sccm was changed by Δq to 150 sccm. A column of a sensitivity matrix S_{i,j} then has the following form

$${S}_{i} = \frac{{λ}_{i}^{TA}}{Δ q} = ( \begin{matrix}- 0.0322 nm / sccm \\ - 0.0021 nm / sccm \\ 0.0069 nm / sccm \\ 0.0093 nm / sccm \\ 0.018 nm / sccm\end{matrix} ) \qquad ( 25 )$$

In the exemplary embodiment, the substrate holders 5 and the orifices 16′, 17′, 8′, 23′ are arranged symmetrically with respect to the axis of rotation 20, so that it may be assumed that the change to one of the individual parameters assigned to the substrates 7 is the same as the change to the individual parameters assigned to each of the substrates 7. The other columns of the sensitivity matrix S_{i,j} may then be created by cyclic substitution as shown in the following table.

| | SH 1 | | SH 2 | | SH 3 | | SH 4 | | SH 5 |
|---|---|---|---|---|---|---|---|---|---|
| Sensitivity SH 1 | −0.0322 | [symbol] | 0.0180 | [symbol] | 0.0093 | [symbol] | 0.0069 | [symbol] | −0.0021 |
| Sensitivity SH 2 | −0.0021 | [symbol] | −0.0322 | [symbol] | 0.0180 | [symbol] | 0.0093 | [symbol] | 0.0069 |
| Sensitivity SH 3 | 0.0069 | [symbol] | −0.0021 | [symbol] | −0.0322 | [symbol] | 0.0180 | [symbol] | 0.0093 |
| Sensitivity SH 5 | 0.0093 | [symbol] | 0.0069 | [symbol] | −0.0021 | [symbol] | −0.0322 | [symbol] | 0.0180 |
| Sensitivity SH 5 | 0.0180 | | 0.0093 | | 0.0069 | | −0.0021 | | −0.0322 |

By forming an inverted sensitivity matrix

$${S}_{i , j}^{- 1} ,$$

correction parameters Δqᵢ can be calculated with the method described above and the correction values Δλᵢ specified in equation 19

$$Δ {q}_{j} = ( \begin{matrix}17 , 4 sccm \\ - 43 , 8 sccm \\ - 1 , 1 sccm \\ 2 , 9 sccm \\ 24 , 7 sccm\end{matrix} ) \qquad ( 23 )$$

With these correction parameters Δqᵢ, target parameters

$${q}_{i}^{Z}$$

may then be set in the form of corrected flows to the orifices 8′, 16′, 17′, 23′ using the relationship specified in equations 19 and 20.

These correction values Δλᵢ and target parameters

$${q}_{i}^{Z}$$

may be stored in the memory of the control device 22.

In a variant of the method, for example after the first preliminary test which has been carried out with the parameter vector specified in equation 21, a vector may also be established from second starting values

$${λ}_{i}^{′ S} ,$$

while the first values Δᵢ, which are Bragg reflections, the second values

$${λ}_{i}^{′}$$

may be temperatures. Second test values

$${λ}_{i}^{′ T}$$

may be determined after the second preliminary test, which was carried out with the test parameters specified in equation 23, for example. A second sensitivity matrix

$${S}_{i , j}^{′}$$

may then be created in a similar way to the method described above. After formation of a second inverted sensitivity matrix, further correction values, correction parameters, etc. can be calculated with the method described above.

In an exemplary embodiment of the invention, it may further be provided that a value λᵢ, for example a Bragg reflection or a layer thickness or a temperature measured during the method, is influenced by two different individual parameters λᵢ. For example, these values λᵢ may be influenced by both a mass flow that creates a gas cushion 6 and by a mass flow of a temperature-control gas flowing through the gap 13. The values λᵢ may be influenced to differing degrees by the various individual parameters qᵢ. In this variant, second test values

$${λ}_{i}^{′ T}$$

are also determined and second sensitivity matrices

$${S}_{i , j}^{′}$$

are calculated in similar manner. This may then be used to make predictions as to the extent to which the various individual parameters qᵢ influence the values λᵢ, possibly to differing degrees.

A parameter optimization may also be carried out by forming one or two inverted matrices

$${S}_{i , j}^{- 1} .$$

The preceding notes serve to explain the inventions covered as a whole by the application, each of which also independently develop the state of the art at least through the following combinations of features, wherein two, several or all of said combinations of features may themselves also be combined, namely:

A method which is characterized in that in a first preliminary test a starting layer or starting layer sequence is deposited on each of a multiplicity of first substrates 7 simultaneously with a first set of individual starting parameters

$${q}_{i}^{S} ,$$

that starting values

$${λ}_{i}^{S}$$

of the layer property are determined on the starting layers or starting layer sequences, or starting values

$${λ}_{i}^{S}$$

of the local variable are measured when depositing the starting layers or starting layer sequence, that in one or more second preliminary tests a test layer or test layer sequence is deposited on each of a multiplicity of second substrates 7 simultaneously with a second set of individual test parameters

$${q}_{i}^{T} ,$$

that test values

$${λ}_{i}^{T}$$

of the layer property are determined on the test layers or test layer sequences, or test values

$${λ}_{i}^{T}$$

of the local variable are measured when depositing the test layers or test layer sequences, and that at least one sensitivity matrix S_{i,j} is formed at least from the test values

$${λ}_{i}^{T}$$

of the layer property or of the local variable, the elements of which each represent the influence of a change in each of the individual parameters qᵢ on each of the values λᵢ of the layer property or the local variable.

A method for setting up an apparatus for the simultaneous deposition of layers or layer sequences on substrates 7 arranged at different storage locations 5′ in a process chamber 2, wherein according to the method according to claim 1 at least one sensitivity matrix S_{i,j} is formed, an inverted sensitivity matrix

$${S}_{i , j}^{- 1}$$

is formed by inverting the sensitivity matrix S_{i,j}, and individual correction parameters Δqᵢ, individual target parameters

$${q}_{i}^{Z}$$

or individual correction factors for correcting the individual parameters are formed with the inverted sensitivity matrix

$${S}_{i , j}^{- 1}$$

in order to achieve specified target values

$${λ}_{i}^{Z}$$

of the values λᵢ.

A method which is characterized in that the individual parameters qᵢ are values of gas flows or heat flows that are directed to substrates 7 arranged at the various storage locations 5′ in the same process chamber 2.

A method which is characterized in that the apparatus includes a multiplicity of identically designed substrate holders 5, each of which carries one or more substrates 7, and the individual parameters qᵢ influence a purge gas flow, a heat flow or a process gas flow to the substrate holder 5.

A method which is characterized in that when the first preliminary test is carried out the individual starting parameters

$${q}_{i}^{S}$$

have the same value as each another.

A method which is characterized in that in the one or more second preliminary tests only one of each of the individual test parameters

$${q}_{i}^{T}$$

differs from all other individual test parameters

$${q}_{i}^{T}$$

by a parameter difference Δq.

A method which is characterized in that the substrates 7, or the substrate holders 5 carrying the substrates 7, or the substrate holders 5 and storage locations storing the substrates 7 are arranged symmetrically in the process chamber 2, and only one second preliminary test is carried out in which only one of the individual test parameters

$${q}_{i}^{T}$$

differs from une ouler, muwany Identical individual test parameters by

$${q}_{i}^{T}$$

by a parameter difference Δq, wherein a first column of the sensitivity matrix S_{i,j} is formed with the test values

$${λ}_{i}^{T}$$

of the layer properties obtained therefrom, and the remaining columns of the sensitivity matrix S_{i,j} are formed by cyclic substitution of the test values

$${λ}_{i}^{T} .$$

A method which is characterized in that a quotient of a difference value and a parameter difference Δq is used to form an element of the sensitivity matrix S_{i,j}, wherein the difference value is a difference between the test value and an average

$${λ}_{i}^{T}$$

and an average value λ̅ of the starting values

$${λ}_{i}^{S} ,$$

a difference between the test value

$${λ}_{i}^{T}$$

and the starting value

$${λ}_{i}^{S} ,$$

or a difference between a difference of the test value

$${λ}_{i}^{T}$$

and an average value λ̅ of the test values

$${λ}_{i}^{T}$$

and of the starting value

$${λ}_{i}^{S}$$

and an average value λ̅ of the starting values

$${λ}_{i}^{S}$$

respectively.

A method which is characterized in that the individual correction parameters Δqᵢ are formed by multiplying the inverted sensitivity matrix

$${S}_{i , j}^{- 1}$$

with a vector having correction values Δλᵢ, and/or that the individual correction value Δλᵢ is a difference between the starting value

$${λ}_{i}^{S}$$

and the target value

$${λ}_{i}^{Z} ,$$

and/or that the individual correction factor kᵢ is the quotient of a sum from the starting parameter

$${q}_{i}^{S}$$

and the correction parameter Δqᵢ on the one hand and the starting value

$${λ}_{i}^{S}$$

on the other hand.

A method which is characterized in that the individual parameter qᵢ is a gas flow or a composition of a gas flow with which a gas cushion 6 that carries a substrate holder 5 is generated, which is heated from below by heating a susceptor 3 with a heating device 11, and/or that the individual parameter qᵢ is a gas flow or a composition of a gas flow with which a heat transport between a temperature-control device 11 and a susceptor 3 may be influenced, and/or that the individual parameter qᵢ is a gas flow of a process gas which contains elements that make up the deposited layer or layer sequence or which dopes them.

A method which is characterized in that by applying the method according to any one of the preceding claims several times in succession, multiple sensitivity matrices S_{i,j} are formed for identical or different target values

$${λ}_{i}^{Z}$$

and different individual parameters qᵢ.

A method which is characterized in that in order to predict the change of second values

$${λ}_{i}^{′}$$

of the layer property of layers or layer sequences deposited on multiple substrates 7 arranged on spatially separate storage locations 5′ in the process chamber 2, or of a local variable that influences the layer growth, the starting values

$${λ}_{i}^{S}$$

obtained with the first set of individual starting parameters q^{S} are used and in further one or more third preliminary tests a second test layer or second test layer sequence is deposited on each of a multiplicity of third substrates 7 simultaneously with a third set of second test parameters

$${q}_{i}^{′ T}$$

assigned to another individual parameter qᵢ, which are different from the first test parameters

$${q}_{i}^{T} ,$$

wherein second test values

$${λ}_{i}^{′ T}$$

of the layer property are determined on the second test layers or second test layer sequences, or second test values

$${λ}_{i}^{′ T}$$

of the local variable are measured during the deposition of the second test layers or second test layer sequences, and at least one second sensitivity matrix

$${S}_{i , j}^{′}$$

is formed from the second test values

$${λ}_{i}^{′ T}$$

of the layer property or the local variable, the elements of which each determine the influence of a change in each of the other individual parameters qᵢ on each of the second target values

$${λ}_{i}^{′ Z}$$

of the layer property or the local variable.

A method which is characterized in that in a first application of the method the individual parameter

$${q}_{i}^{′}$$

is a gas flow with which a gas cushion supporting the local substrate holder 5 is generated, and the target value

$${λ}_{i}^{′ Z}$$

is the layer thickness of the layer or at least one layer of the layer sequence, and that in a subsequent, second application of the method, the individual parameter qᵢ is a gas flow with which a heat transport from a heating device 11 to the substrate 7 is influenced, and the target value

$${λ}_{i}^{′ Z}$$

is the temperature of the substrate 7 when the layer is deposited, or also the layer thickness of the layer or of at least one layer of the layer sequence.

An apparatus which is characterized in that correction factors kᵢ for correcting the individual parameters qᵢ, with which the individual parameters qᵢ provided by the recipe are corrected, are stored in the control device 22.

An apparatus which is characterized in that a sensitivity matrix S_{i,j} or inverted sensitivity matrix

$${S}_{i , j}^{- 1}$$

according to any one of the preceding claims is formed and used to determine the correction factors kᵢ.

A method which is characterized in that the individual parameters qᵢ are corrected with correction factors kᵢ, which are determined in particular according to any one of claims 1 to 12.

A control program for controlling the valves 19 and mass flow controllers 18 of an apparatus according to either of claim 13 or 14 for carrying out the method according to claim 15.

All of the features disclosed are essential to the invention (in isolation, but also in combination with one another). The disclosure of the application hereby also includes the disclosure content of the associated/attached priority documents (copy of the prior application) in full, also for the purpose of including features of these documents in claims of the present application. With their features, even without the features of a referenced claim, the subclaims characterize independent inventive developments of the prior art, in particular in order to make divisional applications on the basis of these claims. The invention described in each claim may additionally include one or more of the features specified in the above description, in particular those provided with reference numbers and/or specified in the list of reference numbers. The invention also relates to designs in which individual features mentioned in the above description are not implemented, in particular insofar as they are clearly dispensable for the respective intended use or may be replaced by other technically equivalent means.

List of reference symbols

| | |
|---|---|
| 1 | Reactor housing |
| 2 | Process chamber |
| 3 | Susceptor |
| 3′ | Top side |
| 3″ | Underside |
| 4 | Pocket |
| 5′ | Storage location |
| 5 | Substrate holder |
| 6 | Gas cushion |
| 7 | Substrate |
| 8 | Feed line |
| 8′ | Orifice |
| 9 | Gas inlet element |
| 10 | Gas outlet element |
| 11 | Heating device |
| 12 | Sealing plate |
| 13 | Gap |
| 14 | Process chamber ceiling |
| 15 | Cooling device |
| 16 | Feed line |
| 16′ | Orifice |
| 17 | Feed line |
| 17′ | Orifice |
| 18 | Mass flow controller |
| 19 | Valve |
| 20 | Axis of rotation |
| 21 | Axis of rotation |
| 22 | Control device |
| 23 | Feed line |
| 23′ | Orifice |
| λᵢ | Value |
| ${λ}_{i}^{′}$ | Second value |
| ${λ}_{i}^{S}$ | Starting value |
| ${λ}_{i}^{′ S}$ | Second starting value |
| ${λ}_{i}^{Z}$ | Target value |
| ${λ}_{i}^{′Z}$ | Second target value |
| ${λ}_{i}^{TA}$ | Test response |
| Δλᵢ | Correction value |
| ${λ}_{i}^{T}$ | Test value |
| ${λ}_{i}^{′T}$ | Second test value |
| λ̅ | Mean value |
| $\overline{{λ}^{S}}$ | Mean value of the starting values |
| $\overline{{λ}^{T}}$ | Mean value of the test values |
| qᵢ | Individual parameter |
| ${q}_{i}^{S}$ | Starting parameter |
| ${q}_{i}^{T}$ | Test parameter |
| ${q}_{i}^{′T}$ | Second test parameter |
| ${q}_{i}^{Z}$ | Target parameter |
| Δqᵢ | Correction parameter |
| q₀ | Uniform parameter |
| Δq | Parameter difference |
| S_{i,j} | Sensitivity matrix |
| ${S}_{i , j}^{′}$ | Second sensitivity matrix |
| ${S}_{i , j}^{- 1}$ | Inverted sensitivity matrix |
| kᵢ | Correction factor |

What is claimed is:

1. A method for creating a sensitivity matrix, S_{i,j}, with elements that indicate an influence of each change in a treatment parameter on layer property values, λᵢ, (i) of layers or layer sequences deposited on a plurality of substrates (7) arranged at spatially separate storage locations (5′) in a process chamber (2) or (ii) of a local variable influencing a layer growth at the storage location (5′), the method comprising:
feeding gases into the process chamber (2) with treatment parameters and/or temperatures in the process chamber (2) that are set to influence the values, λᵢ, of the layer property of the deposited layer or the local variable;
forming in preliminary tests the sensitivity matrix, S_{i,j}, with which individual correction parameters, Δq, individual target parameters,
$${q}_{i}^{Z} ,$$
or individual correction factors, kᵢ, are formed for correcting individual parameters, qᵢ, individually assigned to each of the storage locations (5′) in order to achieve predetermined target values,
$${λ}_{i}^{Z} ,$$
for the values, λᵢ; and
forming the treatment parameters by the individual parameters,
wherein the individual parameters, qᵢ, each have an identical effect on the layer property or the local variable at the respective storage location (5′) to which the individual parameter, qᵢ, is assigned, and
wherein a change in one of the individual parameters, qᵢ, at a first one of the storage locations (5′) influences the values, λᵢ, at other ones of the storage locations (5′).

2. The method of claim 1,
wherein in a first one of the preliminary tests, a starting layer or starting layer sequence is deposited on each of a plurality of first substrates (7) simultaneously with a first set of individual starting parameters,
$${q}_{i}^{S} ,$$
wherein starting values,
$${λ}_{i}^{S} ,$$
of the layer property are determined on the starting layers or starting layer sequence, or starting values,
$${λ}_{i}^{S} ,$$
of the local variable are measured when depositing the starting layers or starting layer sequence,
wherein in a second one of the preliminary tests, a test layer or test layer sequence is deposited on each of a plurality of second substrates (7) simultaneously with a first set of individual test parameters,
$${q}_{i}^{T} ,$$
wherein test values,
$${λ}_{i}^{T} ,$$
of the layer property are determined on the test layers or test layer sequence, or test values,
$${λ}_{i}^{T} ,$$
of the local variable are measured when depositing the test layers or test layer sequence, and
wherein the sensitivity matrix, S_{i,j}, is formed at least from the test values
$${λ}_{i}^{T} ,$$
of the layer property or of the local variable.

3. A method for setting up an apparatus for a simultaneous deposition of layers or layer sequences on substrates (7) arranged at spatially separate storage locations (5′) in a process chamber (2), the method comprising:
forming the sensitivity matrix, S_{i,j}, in accordance with the method of claim 1;
inverting the sensitivity matrix, S_{i,j}, so as to form an inverted sensitivity matrix, S⁻¹_{i,j}, and
forming one or more of the individual correction parameters, Δqᵢ, the individual target parameters,
$${q}_{i}^{Z} ,$$
of the individual correction factors, kᵢ, with the inverted sensitivity matrix,
$${S}_{i , j}^{- 1}$$
.

4. (canceled)

5. The method of claim 3, wherein the apparatus comprises a plurality of substrate holders (5) that are identical to one another, each of which carries one or more of the substrates (7), and the individual parameters, qᵢ, influence one or more of a purge gas flow, a heat flow or a process gas flow to the respective substrate holders (5).

6. The method of claim 2,
wherein in the first preliminary test, the individual starting parameters,
$${q}_{i}^{S} ,$$
all have an identical value, and
wherein in the second preliminary test, only one of the individual test parameters,
$${q}_{i}^{T} ,$$
differs from all other individual test parameters,
$${q}_{i}^{T} ,$$
by a parameter difference, Δq.

7. (canceled)

8. The method of claim 2,
wherein the substrates (7), or substrate holders (5) carrying the substrates (7), or the substrate holders (5) and storage locations (5′) storing the substrates (7) are arranged symmetrically in the process chamber (2),
wherein the second preliminary test is carried out in which only one of the individual test parameters
$${q}_{i}^{T} ,$$
differs from the others by a parameter difference, Δq, and
wherein a first column of the sensitivity matrix, S_{i,j}, is formed with the test values,
$${λ}_{i}^{T} ,$$
of the layer properties obtained therefrom, and remaining columns of the sensitivity matrix, S_{i,j}, are formed by a cyclic substitution of the test values,
$${λ}_{i}^{T}$$
.

9. The method of claim 2,
wherein a quotient of a difference value and a parameter difference, Δq, is used to form an element of the sensitivity matrix, S_{i,j}, and
wherein the difference value is one of a difference between one of the test values,
$${λ}_{i}^{T} ,$$
and an average value, λ̅, of the starting values,
$${λ}_{i}^{T} ,$$
a difference between one of the test values,
$${λ}_{i}^{T} ,$$
and one of the starting values,
$${λ}_{i}^{S} ,$$
or a difference between (i) a difference of one of the test values,
$${λ}_{i}^{T} ,$$
and an average value, λ̅, of the test values,
$${λ}_{i}^{T} ,$$
and of the starting values,
$${λ}_{i}^{S} ,$$
and an average value, \hat{λ}, of the starting values,
$${λ}_{i}^{S} ,$$
.

10. The method of claim 3, wherein the individual correction parameters, Δqᵢ, are formed by multiplying the inverted sensitivity matrix,
$${S}_{i , j}^{- 1} ,$$
with a vector having correction values, Δλᵢ.

11. The method of claim 1, wherein one of:
the respective individual parameters, qᵢ, specify a rate or a composition of a first gas flow with which a gas cushion (6) which carries a substrate holder (5) is generated, the substrate holder (5) being heated from below by heating a susceptor (3) with a heating device (11),
the respective individual parameters, qᵢ, specify a rate or a composition of a second gas flow with which a heat transport between a temperature control device (11) and the susceptor (3) is influenced,
the respective individual parameters, qᵢ, specify a rate of a third gas flow of a process gas that contains elements of (i) which the deposited layer or layer sequence consists or (ii) which dopes the deposited layer or layer sequence, or
the respective individual parameters, qᵢ, specify a rate of a fourth gas flow or heat flow values that are directed to the substrates (7) arranged on the storage locations (5′) in the process chamber (2).

12-13. (canceled)

14. A method, comprising applying the method of claim 3 several times in succession,
wherein by applying the method of claim 3, several times in succession, multiple sensitivity matrices, S_{i,j}, are formed for the target values,
$${λ}_{i}^{Z} ,$$
and the individual parameters, qᵢ,
wherein the target values,
$${λ}_{i}^{Z} ,$$
are identical or different from one another, and
wherein the individual parameters, qᵢ, are different from one another.

15. The method of claim 2, further comprising:
predicting a change of second values,
$${λ}_{i}^{′} ,$$
of the layer property of layers or layer sequences deposited on the substrates (7) arranged on the spatially separate storage locations (5′) in the process chamber (2), or of the local variable that influences the layer growth based on the starting values,
$${λ}_{i}^{S} ,$$
obtained with the first set of individual starting parameters, q^{S};
in a third one of the preliminary tests, depositing a second test layer or second test layer sequence on each of a plurality of third substrates (7) simultaneously with a second set of individual test parameters,
$${q}_{i}^{′ T} ,$$
assigned to another individual parameter, qᵢ, which are different from the first set of individual test parameters,
$${q}_{i}^{T} ;$$
determining second test values,
$${λ}_{i}^{′ T} ,$$
of the layer property on the second test layers or second test layer sequence, or measuring second test values,
$${λ}_{i}^{′ T} ,$$
of the local variable during the deposition of the second test layers or second test layer sequence, and
forming at least one second sensitivity matrix,
$${S}_{i , j}^{′} ,$$
from the second test values,
$${λ}_{i}^{′ T} ,$$
of the layer property or the local variable, the elements of which each determine an influence of a change in each of the other individual parameters, qᵢ, on each of the second target values,
$${λ}_{i}^{′ Z} ,$$
of the layer property or the local variable.

16. The method of claim 2, further comprising:
predicting a change of the values, Δᵢ, of the layer property in a third one of the preliminary tests by depositing a second test layer or second test layer sequence on each of a multiplicity of third substrates (7) simultaneously with a second set of individual test parameters,
$${q}_{i}^{′ T} ,$$
assigned to another individual parameter, qᵢ, which are different from the first set of individual test parameters,
$${q}_{i}^{T} ;$$
determining second test values,
$${λ}_{i}^{′ T} ,$$
of the same layer property on the second test layers or second test layer sequences, or measuring second test values,
$${λ}_{i}^{′ T} ,$$
of the same local variable during the deposition of the second test layers or second test layer sequence; and
forming at least one second sensitivity matrix,
$${S}_{i , j}^{′} ,$$
from the second test values,
$${λ}_{i}^{′ T} ,$$
of the layer property or the same local variable, the elements of which each determine an influence of a change in each of the other individual parameters, qᵢ, on each of the target values,
$${λ}_{i}^{′ Z} ,$$
of the layer property of the local variable.

17. A method comprising:
applying, in a first application, the method of claim 14; and
applying, in a second application subsequent to the first application, the method of claim 14,
wherein in the first application of the method of claim 14, an individual parameter,
$${q}_{i}^{′} ,$$
is a gas flow with which a gas cushion supporting a local one of the substrate holders (5) is generated, and a target value,
$${λ}_{i}^{′ Z} ,$$
is a layer thickness of the layer or at least one layer of the layer sequence, and
wherein in the second application of the method of claim 14, the individual parameter, qᵢ, is a gas flow rate with which a heat transport from a heating device (11) to the substrate (7) is influenced, and the target value,
$${λ}_{i}^{′ Z} ,$$
is a temperature of the substrate (7) when the layer is deposited, or the layer thickness of the layer or of at least one layer of the layer sequence.

18. An apparatus for depositing a layer or layer sequence on a plurality of substrates (7), comprising:
a reactor housing (1);
a process chamber (2) arranged in the reactor housing (1);
a gas mixing device having valves (19) and mass flow controllers (18);
a susceptor (3) arranged in the process chamber (2) with storage locations (5′) for the plurality of substrates (7);
a control device (22); and
a gas inlet element (9) for introducing process gases provided in the gas mixing device according to a recipe stored in the control device (22),
wherein the control device (22) is configured to direct gas flows or heat flows independently of one another to different ones of the substrates (7) or to substrate holders (5) carrying one or more of the substrates (7) according to individual parameters, qᵢ, specified by the recipe,
wherein correction factors, kᵢ, for correcting the individual parameters, qᵢ, are stored in the control device (22), with which the individual parameters, qᵢ, provided by the recipe are corrected, and
wherein the individual parameters, qᵢ, which are determined in accordance with the method of claim 1.

19. A method for simultaneously depositing a layer or layer sequence on respective ones of a plurality of substrates (7) in a process chamber (2), the method comprising:
feeding gases into the process chamber (2) according to treatment parameters and/or temperatures that are set in the process chamber (2),
wherein the treatment parameters contain individual parameters, qᵢ, assigned individually to each of the substrates (7), the individual parameters, qᵢ, being individually changeable,
wherein one of:
a change in a first one of the individual parameters, qᵢ, not only results in a change in a value, λᵢ, of a layer property of the layer or layer sequence deposited with the changed first individual parameter, qᵢ, on a corresponding first one of the substrates (7) but also results in a change in a value, λᵢ, of the layer property of a layer or layer sequence deposited on one of the substrates (7) other than the first substrate (7), or
a change in a first one of the individual parameters, qᵢ, not only results in a change in a value, λᵢ, of a local variable influencing the layer growth at the storage location (5′) of a corresponding first one of the substrates (7), but also results in a change in the local variable at other storage locations (5′), and
wherein the individual parameters, qᵢ, are corrected with correction factors, kᵢ, which are determined in accordance with the method of claim 1.

20. A control program for controlling the valves (19) and mass flow controllers (18) of an apparatus for carrying out the method of claim 19.

21. (canceled)

22. The method of claim 2, wherein at least one of:
one of the individual correction values, Δλᵢ, is a difference between one of the starting values,
$${λ}_{i}^{S} ,$$
and one of the target values,
$${λ}_{i}^{Z} ;$$
or
one of the individual correction factors, kᵢ, is a quotient between (i) a sum of the starting parameter,
$${q}_{i}^{S} ,$$
and the correction parameter, Δqᵢ and (ii) the starting parameter,
$${q}_{i}^{S} .$$
